(19) United States
(12) Patent Application Publication
(10) Pub. No.: US 2026/0247728 A1
(43) Pub. Date: Aug. 20, 2026

(54) SOLID-STATE IMAGING DEVICE

(71) Applicant: SONY SEMICONDUCTOR SOLUTIONS CORPORATION, KANAGAWA (JP)

(72) Inventors: MASASHI KINO, KUMAMOTO (JP); KAZUKI YAMAGUCHI, KUMAMOTO (JP)

(21) Appl. No.: 19/489,602

(22) PCT Filed: May 15, 2024
(86) PCT No.: PCT/JP2024/017883

§ 371 Date: Dec. 3, 2025

(30) Foreign Application Priority Data
Jun. 26, 2023 (JP) 2023-104485

(51) Int. Cl. H10F 39/00

(52) U.S. Cl. CPC H10F 39/8037

(57) ABSTRACT

There is provided a solid-state imaging device capable of suitably forming a transistor on an SOI structure. A solid-state imaging device of the present disclosure includes: a semiconductor substrate; an insulating film provided on the semiconductor substrate; a semiconductor layer provided on the insulating film; and a plurality of transistors including one or more first transistors and one or more second transistors, the one or more first transistors each including a source/drain region in the semiconductor substrate, the one or more second transistors each including a source/drain region in the semiconductor layer, in which the plurality of transistors includes: a low-voltage transistor including a gate insulating film having a first film thickness; a first high-voltage transistor that includes a gate insulating film having a second film thickness larger than the first film thickness and has a first threshold voltage; and a second high-voltage transistor that includes a gate insulating film having the second film thickness and has a second threshold voltage lower than the first threshold voltage, and the second high-voltage transistor is included in the second transistors.

### TECHNICAL FIELD

The present disclosure relates to a solid-state imaging device.

### BACKGROUND ART

In a solid-state imaging device such as a CMOS image sensor (CIS), a comparison circuit and a load circuit in an analog to digital (AD) converter are generally configured with not a low voltage (LV) transistor but a high voltage (HV) transistor. The HV transistor includes an SVT transistor having a high threshold voltage and a ULVT transistor having a low threshold voltage.

The ULVT transistor can output a large current. Therefore, the comparison circuit and the load circuit in the AD converter are generally configured with ULVT transistors in order to reduce noise. However, since the ULVT transistor has a large leakage current, there is a problem that power consumption is large.

### CITATION LIST

### Patent Document

Patent Document 1: Japanese Patent Application Laid-Open No. 2006-165808

Patent Document 2: Japanese Patent Application Laid-Open No. 2011-211213

### SUMMARY OF THE INVENTION

### Problems to be Solved by the Invention

In order to reduce power consumption of the solid-state imaging device, it is conceivable to form all the transistors of the solid-state imaging device on a full depletion semiconductor on insulator (FD-SOI) substrate instead of on a bulk semiconductor substrate. The FD-SOI substrate has an SOI structure in which an insulating film and a semiconductor layer are sequentially provided on a semiconductor substrate.

Employing the FD-SOI substrate makes it possible to reduce the leakage current of these transistors, and to reduce the power consumption of the solid-state imaging device. However, it is necessary to recreate the models of these transistors from the model for the bulk semiconductor substrate to the model for the FD-SOI substrate, which causes a large amount of labor and cost.

Therefore, the present disclosure provides a solid-state imaging device capable of suitably forming a transistor on an SOI structure.

### Solutions to Problem

A solid-state imaging device according to a first aspect of the present disclosure includes: a semiconductor substrate; an insulating film provided on the semiconductor substrate; a semiconductor layer provided on the insulating film; and a plurality of transistors including one or more first transistors and one or more second transistors, the one or more first transistors each including a source/drain region in the semiconductor substrate, the one or more second transistors each including a source/drain region in the semiconductor layer, in which the plurality of transistors includes: a low-voltage transistor including a gate insulating film having a first film thickness; a first high-voltage transistor that includes a gate insulating film having a second film thickness larger than the first film thickness and has a first threshold voltage; and a second high-voltage transistor that includes a gate insulating film having the second film thickness and has a second threshold voltage lower than the first threshold voltage, and the second high-voltage transistor is included in the second transistors.

This makes it possible to suitably form a transistor on the SOI structure. For example, disposing the second high-voltage transistor on the SOI structure makes it possible to reduce the leakage current of the second high-voltage transistor in which the leakage current is likely to be a problem. Furthermore, by limiting the transistors disposed on the SOI structure to some transistors (second transistors) such as the second high-voltage transistors, it is possible to reduce labor and cost for recreating the model.

Furthermore, in the first aspect, the low-voltage transistor may be included in the second transistors. This makes it possible to reduce the leakage current of the low-voltage transistor, for example.

Furthermore, in the first aspect, the low-voltage transistor may be included in the first transistors. This makes it possible to suppress the occurrence of labor and cost for recreating the model of the low-voltage transistor, for example.

Furthermore, in the first aspect, the low-voltage transistor may be provided in a digital circuit. This makes it possible to form the transistor in the digital circuit more suitably with the low-voltage transistor, for example.

Furthermore, in the first aspect, the first high-voltage transistor may be included in the first transistors. This makes it possible to suppress the occurrence of labor and cost for recreating the model of the first high-voltage transistor, for example.

Furthermore, in the first aspect, the first high-voltage transistor may be provided in an analog circuit. This makes it possible to form the transistor in the analog circuit more suitably with the first high-voltage transistor, for example.

Furthermore, in the first aspect, the first high-voltage transistor may be provided in the analog circuit other than a comparison circuit and a load circuit. This makes it possible to form a transistor in an analog circuit other than the comparison circuit and the load circuit with the first high-voltage transistor, and to form a transistor in the comparison circuit or the load circuit with the second high-voltage transistor, for example.

Furthermore, in the first aspect, the second high-voltage transistor may be provided in a comparison circuit or a load circuit. This makes it possible to form the transistor in the comparison circuit or the load circuit more suitably with the second high-voltage transistor, for example.

Furthermore, in the first aspect, the second high-voltage transistor in the comparison circuit may be provided in a differential circuit. This makes it possible to form a differential circuit in the comparison circuit suitably, for example.

Furthermore, in the first aspect, the second high-voltage transistor in the comparison circuit may have a first conductivity type, and the second high-voltage transistor in the load circuit may have a second conductivity type different from the first conductivity type. This makes it possible to make the second high-voltage transistor in the comparison circuit into an N-type MOSFET, and to make the second high-voltage transistor in the load circuit into a P-type MOSFET, for example.

Furthermore, in the first aspect, the semiconductor layer may be formed with the same semiconductor material as the semiconductor substrate. This makes it possible to form the source/drain region of the first transistor and the source/drain region of the second transistor in different semiconductor regions formed with the same semiconductor material, for example.

Furthermore, in the first aspect, the semiconductor material may be silicon. This makes it possible to form the source/drain region of the first transistor and the source/drain region of the second transistor in different semiconductor regions both formed with silicon, for example.

Furthermore, in the first aspect, the insulating film may be an oxide film. This makes it possible to realize an SOI structure including, for example, a silicon substrate, a silicon oxide film, and a silicon layer.

A solid-state imaging device according to a second aspect of the present disclosure includes: a semiconductor substrate; an insulating film provided on the semiconductor substrate; a semiconductor layer provided on the insulating film; and a plurality of transistors including one or more first transistors and one or more second transistors, the one or more first transistors each including a source/drain region in the semiconductor substrate, the one or more second transistors each including a source/drain region in the semiconductor layer, in which the second transistors include a transistor provided in a comparison circuit or a load circuit. This makes it possible to suitably form a transistor on the SOI structure. For example, disposing the transistors in the comparison circuit or the load circuit on the SOI structure makes it possible to reduce the leakage current of the comparison circuit or the load circuit that often include transistors in which the leakage current is likely to be a problem. Furthermore, by limiting the transistors disposed on the SOI structure to some transistors (second transistors) such as the transistors in the comparison circuit or the load circuit, it is possible to reduce labor and cost for recreating the model.

Furthermore, in the second aspect, the transistor in the comparison circuit may be provided in a differential circuit. This makes it possible to form a differential circuit in the comparison circuit suitably, for example.

Furthermore, in the second aspect, the transistor in the comparison circuit may have a first conductivity type, and the transistor in the load circuit may have a second conductivity type different from the first conductivity type. This makes it possible to make the transistor in the comparison circuit into an N-type MOSFET, and to make the transistor in the load circuit into a P-type MOSFET, for example.

Furthermore, in the second aspect, the first transistors may include a transistor provided in an analog circuit other than the comparison circuit and the load circuit. This makes it possible to form the transistor in an analog circuit other than the comparison circuit and the load circuit more suitably with the first transistor, for example.

Furthermore, in the second aspect, the first transistors or the second transistors may include a transistor provided in a digital circuit. This makes it possible to form the transistor in the digital circuit more suitably with the first transistor or the second transistor, for example.

Furthermore, in the second aspect, the plurality of transistors may include: a low-voltage transistor including a gate insulating film having a first film thickness; a first high-voltage transistor that includes a gate insulating film having a second film thickness larger than the first film thickness and has a first threshold voltage; and a second high-voltage transistor that includes a gate insulating film having the second film thickness and has a second threshold voltage lower than the first threshold voltage, and the second high-voltage transistor may be included in the second transistors and provided in the comparison circuit or the load circuit. This makes it possible to form the transistor in the comparison circuit or the load circuit more suitably with the second high-voltage transistor, for example.

Furthermore, in the second aspect, the first high-voltage transistor may be included in the first transistors and provided in an analog circuit other than the comparison circuit and the load circuit, and the low-voltage transistor may be included in the first transistors or the second transistors and provided in a digital circuit. This makes it possible to form a transistor in an analog circuit or a transistor in a digital circuit suitably formed, for example.

### BRIEF DESCRIPTION OF DRAWINGS

FIG. 1 is a block diagram illustrating a configuration of a solid-state imaging device of a first embodiment.

FIG. 2 is a cross-sectional view illustrating a structure of the solid-state imaging device of the first embodiment.

FIG. 3 illustrates cross-sectional views (1/2) illustrating examples of a transistors of the first embodiment.

FIG. 4 illustrates cross-sectional views (2/2) illustrating examples of the transistors of the first embodiment.

FIG. 5 is a cross-sectional view illustrating a structure of the solid-state imaging device of the first embodiment.

FIG. 6 is a cross-sectional view illustrating a structure of a solid-state imaging device of a second embodiment.

FIG. 7 is a block diagram illustrating a configuration example of an electronic device.

FIG. 8 is a block diagram illustrating a configuration example of a moving body control system.

FIG. 9 is a plan view illustrating a specific example of a setting position of an imaging section in FIG. 8.

FIG. 10 is a view illustrating an example of a schematic configuration of an endoscopic surgical system.

FIG. 11 is a block diagram illustrating an example of a functional configuration of a camera head and a camera control unit (CCU).

### MODE FOR CARRYING OUT THE INVENTION

Hereinafter, embodiments of the present disclosure will be described with reference to the drawings.

### First Embodiment

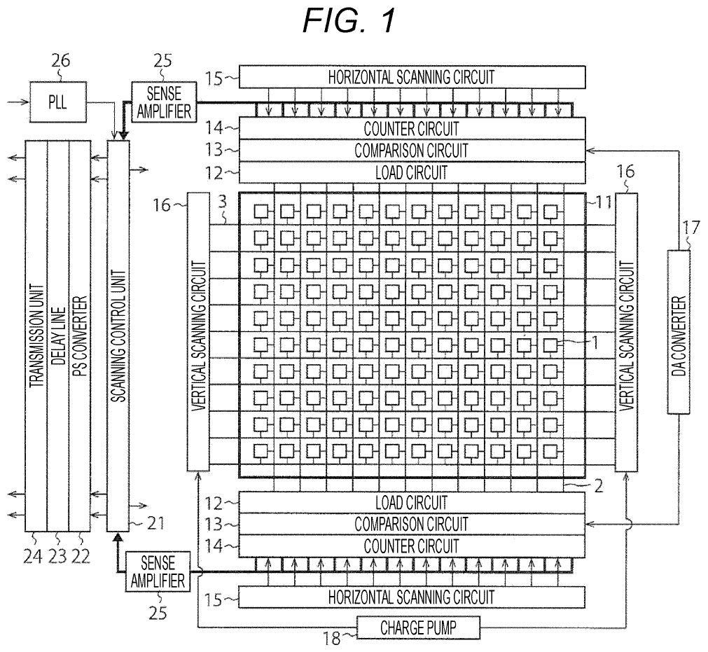

FIG. 1 is a block diagram illustrating a configuration of a solid-state imaging device of a first embodiment. The solid-state imaging device of the present embodiment is, for example, an image sensor such as a CIS.

The solid-state imaging device according to the present embodiment includes a pixel array region 11, a plurality of load circuits 12, a plurality of comparison circuits 13, a plurality of counter circuits 14, a plurality of horizontal scanning circuits 15, a plurality of vertical scanning circuits 16, a digital to analog (DA) converter 17, a charge pump 18, a scanning control unit 21, a parallel to serial (PS) converter 22, a delay line 23, a transmission unit 24, a plurality of sense amplifiers 25, and a phase locked loop (PLL) 26.

The pixel array region 11 includes a plurality of pixels 1 arranged in a two-dimensional array, a plurality of vertical signal lines 2 extending in a vertical direction (column direction), and a plurality of horizontal signal lines 3 extending in a horizontal direction (row direction). Each of the pixels 1 includes a photodiode functioning as a photoelectric conversion section and a MOS transistor functioning as a pixel transistor. Examples of the pixel transistor include a transfer transistor, a reset transistor, an amplifying transistor, a selection transistor, and a switch transistor. These pixel transistors may be shared by several pixels 1.

The load circuits 12, the comparison circuits 13, the counter circuits 14, and the horizontal scanning circuits 15 are electrically connected to the pixels 1 via the vertical signal lines 2. The vertical scanning circuits 16 are electrically connected to the pixels 1 via the horizontal signal lines 3. The load circuits 12 constitute a source follower circuit together with the pixels 1. The comparison circuits 13 constitute an AD converter together with the load circuits 12 and the counter circuits 14, and this AD converter converts the pixel signal read from the pixel 1 from an analog signal to a digital signal. The comparison circuits 13 compare the pixel signal with the reference signal, and the counter circuits 14 count the time until the comparison result of the comparison circuits 13 is inverted. The horizontal scanning circuits 15 scan the plurality of vertical signal lines 2 (read columns) in the horizontal direction in order to read the pixel signals. On the other hand, the vertical scanning circuits 16 scan the pixels 1 in the vertical direction in units of rows via the plurality of horizontal signal lines 3.

The DA converter 17 converts a pixel signal from a digital signal to an analog signal contrary to the AD converter. The charge pump 18 supplies a predetermined voltage to the vertical scanning circuits 16. The vertical scanning circuits 16 generate a signal for driving the pixel 11 using the voltage supplied from the charge pump 18.

The scanning control unit 21 generates various signals for controlling the operations of the horizontal scanning circuits 15 and the vertical scanning circuits 16 on the basis of a vertical synchronization signal, a horizontal synchronization signal, a reference clock signal, and the like. The signal generated by the scanning control unit 21 is, for example, a clock signal or a control signal.

The PS converter 22 converts the image data obtained from the pixel signal from a parallel signal to a serial signal. This image data is transferred from the PS converter 22 to the transmission unit 24 via the delay line 23, and is output from the transmission unit 24 to the outside of the solid-state imaging device.

The sense amplifier 25 transfers the image data from the pixel array region 11 to the PS converter 22 via the scanning control unit 21. The PLL 26 generates a reference clock signal and supplies the reference clock signal to the scanning control unit 21.

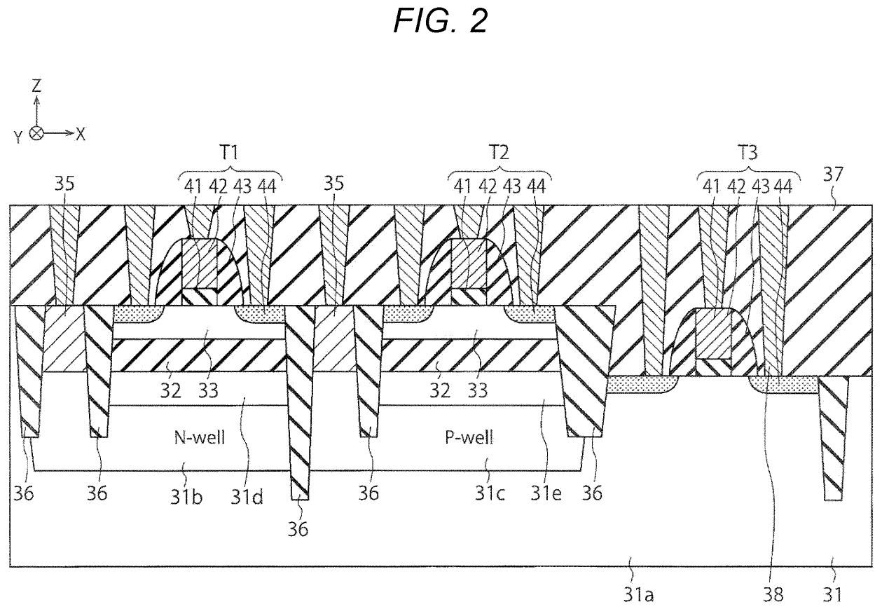

FIG. 2 is a cross-sectional view illustrating a structure of the solid-state imaging device of the first embodiment. FIG. 2 illustrates a vertical cross section of the solid-state imaging device illustrated in FIG. 1.

As illustrated in FIG. 2, the solid-state imaging device of the present embodiment includes a semiconductor substrate 31, an embedded insulating film 32, a semiconductor layer 33, a plurality of contact layers 35, element isolation insulating films 36, an interlayer insulating film 37, a plurality of contact plugs 38, and a plurality of transistors T1 to T3. The embedded insulating film 32 is an example of an insulating film of the present disclosure. The transistor T3 is an example of a first transistor of the present disclosure. The transistors T1 and T2 are each an example of a second transistor of the present disclosure.

FIG. 2 illustrates an X axis, a Y axis, and a Z axis perpendicular to each other. The X direction and the Y direction correspond to the lateral direction, and the Z direction corresponds to the vertical direction. Furthermore, a +Z direction corresponds to an upward direction, and a-Z direction corresponds to a downward direction. Note that the-Z direction may strictly match a gravity direction, or does not necessarily strictly match the gravity direction.

The semiconductor substrate 31 is, for example, a silicon (Si) substrate. The semiconductor substrate 31 according to the present embodiment is a bulk semiconductor substrate (bulk Si substrate). In FIG. 2, the upper surface of the semiconductor substrate 31 is perpendicular to the Z direction. The semiconductor substrate 31 includes a bulk region 31a, an N-well region 31b, a P-well region 31c, a back plate region 31d, and a back plate region 31e.

The N-well region 31b is an N-type region formed on the bulk region 31a. The P-well region 31c is a P-type region formed on the bulk region 31a. The back plate region 31d is formed on the N-well region 31b. The back plate region 31e is formed on the P-well region 31c. The back plate regions 31d and 31e may be N-type regions or P-type regions. In the present embodiment, one of the back plate regions 31d and 31e is an N-type region, and the other of the back plate regions 31d and 31e is a P-type region. One of the N-conductivity type and the P-conductivity type is an example of a first conductivity type of the present disclosure. The other of the N-conductivity type and the P-conductivity type is an example of a second conductivity type of the present disclosure.

The embedded insulating film 32 is formed on the semiconductor substrate 31. The embedded insulating film 32 of the present embodiment is not formed on the entire upper surface of the semiconductor substrate 31, but is formed only on a part of the upper surface of the semiconductor substrate 31. The embedded insulating film 32 is, for example, a SiO₂ film (silicon oxide film). In this case, the embedded insulating film 32 is also called a buried oxide (BOX) film.

The semiconductor layer 33 is formed on the embedded insulating film 32. The embedded insulating film 32 and the semiconductor layer 33 are sequentially formed on the semiconductor substrate 31, and constitute an SOI structure together with the semiconductor substrate 31. The semiconductor layer 33 is formed on the upper surface of the semiconductor substrate 31 via an embedded insulating film 32. Similarly to the embedded insulating film 32, the semiconductor layer 33 of the present embodiment is not formed on the entire upper surface of the semiconductor substrate 31, but is formed only on a part of the upper surface of the semiconductor substrate 31. The semiconductor layer 33 is, for example, a Si layer such as a polysilicon layer. In the present embodiment, the semiconductor substrate 31 and the semiconductor layer 33 are formed with the same semiconductor material (here, silicon). The semiconductor layer 33 is also referred to as an SOI layer.

Each of the transistors Tl to T3 includes a gate insulating film 41, a gate electrode 42, a sidewall insulating film 43, and a source/drain region 44. Each gate insulating film 41 is formed on the semiconductor substrate 31 or the semiconductor layer 33. Each gate electrode 42 is formed on the gate insulating film 41. Each sidewall insulating film 43 is formed on a side surface of the gate electrode 42. Each source/drain region 44 is formed in the semiconductor substrate 31 or the semiconductor layer 33 so as to sandwich the gate electrode 42.

In FIG. 2, the transistors T1 and T2 are formed on the semiconductor layer 33, and the transistor T3 is formed on the semiconductor substrate 31. Therefore, the source/drain region 44 of the transistor T1 and the source/drain region 44 of the transistor T2 are formed in the semiconductor layer 33. On the other hand, the source/drain region 44 of the transistor T3 is formed in the semiconductor substrate 31. In FIG. 2, the transistors T1 and T2 are formed on the SOI structure, whereas the transistor T3 is formed not on the SOI structure but on the bulk semiconductor substrate.

The transistors T1 to T3 of the present embodiment are MOSFETS. These transistors T1 to T3 may be NMOSs or PMOSs. In the SOI structure of the present embodiment, one of the transistors T1 and T2 is an NMOS, and the other of the transistors T1 and T2 is a PMOS.

The contact layer 35 is formed on the N-well region 31b and the P-well region 31c. The contact layer 35 is, for example, a semiconductor layer or a metal layer.

The element isolation insulating films 36 are formed in the semiconductor substrate 31, the embedded insulating film 32, and the semiconductor layer 33 in order to isolate the transistors T1 to T3 from each other. In FIG. 2, the element isolation insulating films 36 are formed between the N-well region 31b and the P-well region 31c, between the semiconductor layer 33 and the contact layer 35, and the like. The element isolation insulating films 36 are, for example, Si02 films. The element isolation insulating films 36 are also called shallow trench isolation (STI) films.

The interlayer insulating film 37 is formed on the semiconductor substrate 31, the embedded insulating film 32, the semiconductor layer 33, the contact layer 35, and the element isolation insulating film 36 so as to cover the transistors T1 to T3. The interlayer insulating film 37 is, for example, a SiO₂ film.

The contact plugs 38 are formed on the contact layer 35, the gate electrodes 42 of the transistors T1 to T3, and the source/drain regions 44 of the transistors T1 to T3, in the interlayer insulating film 37. The N well 31b and the P well 31c are electrically connected to the contact plugs 38 via the contact layer 35. The contact plugs 38 are, for example, a semiconductor layer or a metal layer.

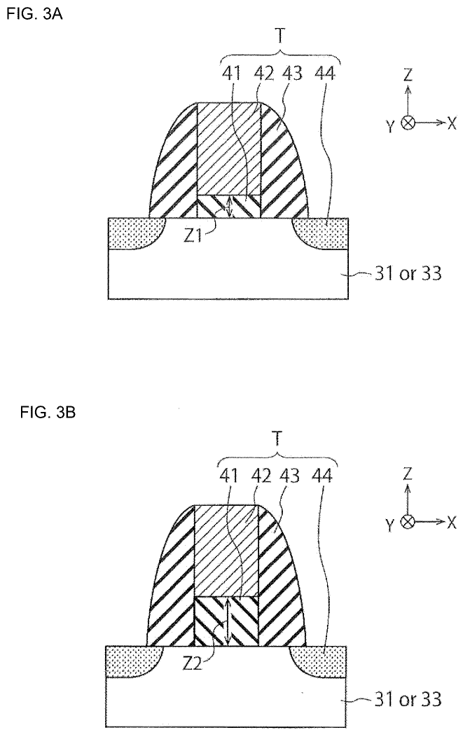

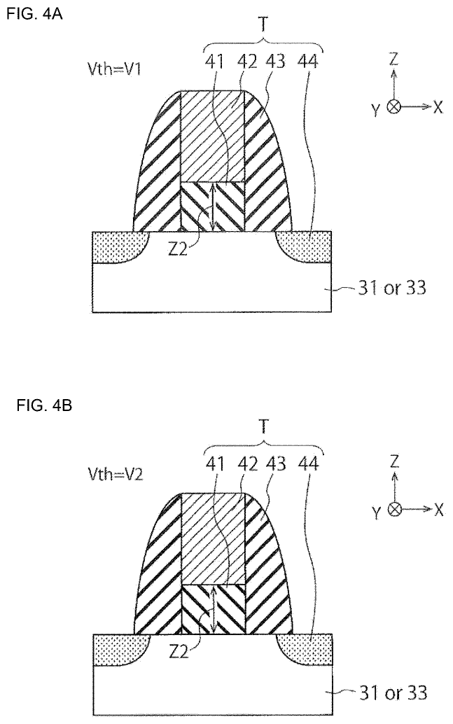

Next, various examples of the transistor of the present embodiment will be described with reference to FIGS. 3 and 4.

The above-described transistors T1 to T3 are included in these examples.

FIGS. 3 and 4 are cross-sectional views illustrating an example of the transistor of the first embodiment.

In each of FIGS. 3A to 4B, the transistor T includes the gate insulating film 41, the gate electrode 42, the sidewall insulating film 43, and the source/drain region 44 described above. The source/drain region 44 is included in the semiconductor substrate 31 or the semiconductor layer 33.

The transistor T illustrated in FIG. 3A is an LV transistor and includes the gate insulating film 41 having a film thickness Z1. The transistor T illustrated in FIG. 3B is an HV transistor, and includes the gate insulating film 41 having a film thickness Z2. The film thickness Z2 is set thicker than the film thickness Z1 (Z2>Z1). The solid-state imaging device according to the present embodiment includes both an LV transistor and an HV transistor. The LV transistor is an example of a low-voltage transistor of the present disclosure. The film thickness Z1 is an example of a first film thickness of the present disclosure. The film thickness 22 is an example of a second film thickness of the present disclosure.

FIGS. 4A and 4B illustrate two types of HV transistors having different threshold voltages Vth. The transistor T illustrated in FIG. 4A is an HV transistor having a threshold voltage V1, and is referred to as an SVT transistor. The transistor T illustrated in FIG. 4B is an HV transistor having a threshold voltage V2, and is referred to as a ULVT transistor. The threshold voltage V2 is set lower than the threshold voltage V1 (V2<V1). The solid-state imaging device according to the present embodiment includes both an SVT transistor and a ULVT transistor. The SVT transistor is an example of a first high-voltage transistor of the present disclosure. The ULVT transistor is an example of a second high-voltage transistor of the present disclosure. The threshold voltage V1 is an example of a first threshold voltage of the present disclosure. The threshold voltage V2 is an example of a second threshold voltage of the present disclosure.

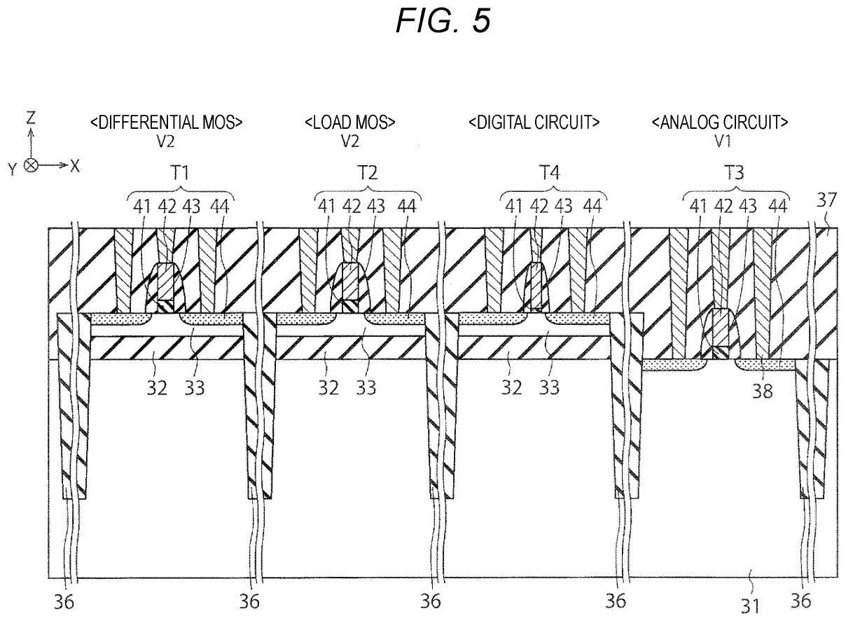

FIG. 5 is a cross-sectional view illustrating a structure of the solid-state imaging device of the first embodiment. The structure of the solid-state imaging device illustrated in FIG. 5 corresponds to an example of a structure of the solid-state imaging device illustrated in FIG. 2.

FIG. 5 illustrates a transistor T4 in addition to the transistors T1 to T3 described above. Similarly to the transistors T1 to T3, the transistor T4 includes the gate insulating film 41, the gate electrode 42, the sidewall insulating film 43, and the source/drain region 44. Note that, in FIG. 5, illustration of a part (N-well region 31b, P-well region 31c, back plate regions 31d and 31e, contact layer 35, and the like) of the components illustrated in FIG. 2 is omitted.

In FIG. 5, the transistors T1, T2, and T4 are formed on the Semiconductor layer 33, and the transistor T3 is formed on the semiconductor substrate 31. Therefore, the source/drain regions 44 of the transistors T1, T2, T4 are formed in the semiconductor layer 33, and the source/drain region 44 of the transistor T3 is formed in the semiconductor substrate 31. In FIG. 5, the transistors T1, T2, and T4 are formed on the SOI structure, whereas the transistor T3 is formed not on the SOI structure but on the bulk semiconductor substrate. The transistor T3 of the present embodiment is an example of a first transistor of the present disclosure, and the transistors T1, T2, and T4 of the present embodiment are each an example of a second transistor of the present disclosure.

In FIG. 5, the transistor T1 is a ULVT transistor and is a differential MOS. The differential MOS is a MOSFET constituting a differential circuit in the comparison circuit 13. Since the transistor T1 is a ULVT transistor, the transistor T1 includes the gate insulating film 41 having the film thickness Z2 and has the threshold voltage V2. The transistor T1 is here an NMOS. For example, each of the comparison circuits 13 of the present embodiment includes a plurality of comparators, and the transistor T1 forms a differential pair in any of the comparators.

Moreover, in FIG. 5, the transistor T2 is a ULVT transistor and is a load MOS. The load MOS is a MOSFET constituting the load circuit 12. Since the transistor T2 is a ULVT transistor, the transistor T2 includes the gate insulating film 41 having the film thickness Z2 and has the threshold voltage V2. The transistor T2 is here a PMOS. For example, each load circuit 14 of the present embodiment includes a plurality of active loads, and the transistor T2 constitutes any one of the active loads.

Moreover, in FIG. 5, the transistor T3 is an SVT transistor and constitutes an analog circuit in the solid-state imaging device of the present embodiment. However, the transistor T3 constitutes an analog circuit other than the comparison circuit 13 and the load circuit 12. Examples of the analog circuit include the DA converter 17 and the charge pump 18. Since the transistor T3 is an SVT transistor, the transistor T3 includes the gate insulating film 41 having the film thickness Z2 and has the threshold voltage V1. Note that the transistor T3 may be an NMOS or a PMOS.

Moreover, in FIG. 5, the transistor T4 is an LV transistor and constitutes a digital circuit in the solid-state imaging device of the present embodiment. Since the transistor T4 is an LV transistor, the transistor T4 includes the gate insulating film 41 having the film thickness Z1. Note that the transistor T4 may be an NMOS or a PMOS.

Next, further details of the solid-state imaging device of the present embodiment will be described with reference to FIG. 5.

In the present embodiment, all the transistors in each comparison circuit 13, and all the transistors in each load circuit 12 are desirably ULVT transistors. The reason is that it is desirable to configure the comparison circuit 13 and the load circuit 12 with a ULVT transistor that outputs a large current, thereby reducing the noise. In this case, the comparison circuit 13 and the load circuit 12 are desirably disposed on the SOI structure. The reason is that in a case where the comparison circuit 13 and the load circuit 12 are configured by ULVT transistors having a large leakage current, power consumption increases.

Therefore, in the present embodiment, all the transistors in each comparison circuit 13 and all the transistors in each load circuit 12 are made ULVT transistors and disposed on the SOI structure like the transistors T1 and T2 illustrated in FIG. 5. This makes it possible to reduce the power consumption of the comparison circuit 13 and the load circuit 12 while reducing the noise of the comparison circuit 13 and the load circuit 12. Since the SOI structure is a fully depleted device, disposing the ULVT transistor on the SOI structure makes it possible to effectively reduce the leakage current of the ULVT transistor. Furthermore, since the operation of the transistor on the SOI structure can be controlled by the back bias, it is possible to expand the dynamic range while reducing the leakage current.

In addition, in the present embodiment, the transistor in the analog circuit other than the comparison circuit 13 and the load circuit 12 is desirably SVT transistor. The reason is that analog circuit other than the comparison circuit 13 and the load circuit 12 is not required to have lower noise than the comparison circuit 13 and the load circuit 12. In this case, the analog circuit other than the comparison circuit 13 and the load circuit 12 may be disposed on a bulk semiconductor substrate. The reason is that the problem of leakage current and power consumption is not so large.

Therefore, in the present embodiment, the transistor in the analog circuit other than the comparison circuit 13 and the load circuit 12 is designed to be an SVT transistor and disposed on the bulk semiconductor substrate as in the transistor T3 illustrated in FIG. 5. This makes it possible to suppress the labor and cost of recreating these transistor models each from the model for the bulk semiconductor substrate to the model for the SOI structure. In this case, an existing intellectual property (IP) can be utilized for these transistors, thereby shortening the development period of the solid-state imaging device.

Furthermore, in the present embodiment, the transistor in the digital circuit is desirably an LV transistor. The reason is that digital circuits generally do not require high voltages as do analog circuits. In this case, it is desirable that the transistor in the digital circuit is disposed on the SOI structure. The reason is that the LV transistor has large power consumption because the film thickness Z1 of the gate insulating film 41 is thin.

Therefore, in the present embodiment, the transistor in the digital circuit is designed to be the LV transistor, and disposed on the SOI structure as in the transistor T4 illustrated in FIG. 5. This makes it possible to reduce power consumption of the digital circuit.

As described above, in the present embodiment, the ULVT transistors in the comparison circuit 13 and the load circuit 12 and the LV transistor in the digital circuit are formed on the SOI structure, and the SVT transistor in the other analog circuit is formed on the bulk semiconductor substrate. Therefore, according to the present embodiment, these transistors can be suitably formed on the SOI structure and the bulk semiconductor substrate. For example, disposing the ULVT transistor on the SOI structure makes it possible to reduce the leakage current of the ULVT transistor in which the leakage current is likely to be a problem. Furthermore, limiting the transistors disposed on the SOI structure to some transistors makes it possible to reduce labor and cost for recreating the model.

Note that the comparison circuit 13 or the load circuit 12 may include not only a ULVT transistor but also an SVT transistor or an LV transistor. In this case, the SVT transistor may be disposed on the bulk semiconductor substrate. Furthermore, the analog circuit other than the comparison circuit 13 and the load circuit 12 may include not only the SVT transistor but also a ULVT transistor or an LV transistor. In this case, the ULVT transistor or the LV transistor may be disposed on the SOI structure. Furthermore, the digital circuit may include not only the LV transistor but also a ULVT transistor or an SVT transistor. In this case, the SVT transistor may be disposed on the bulk semiconductor substrate.

### Second Embodiment

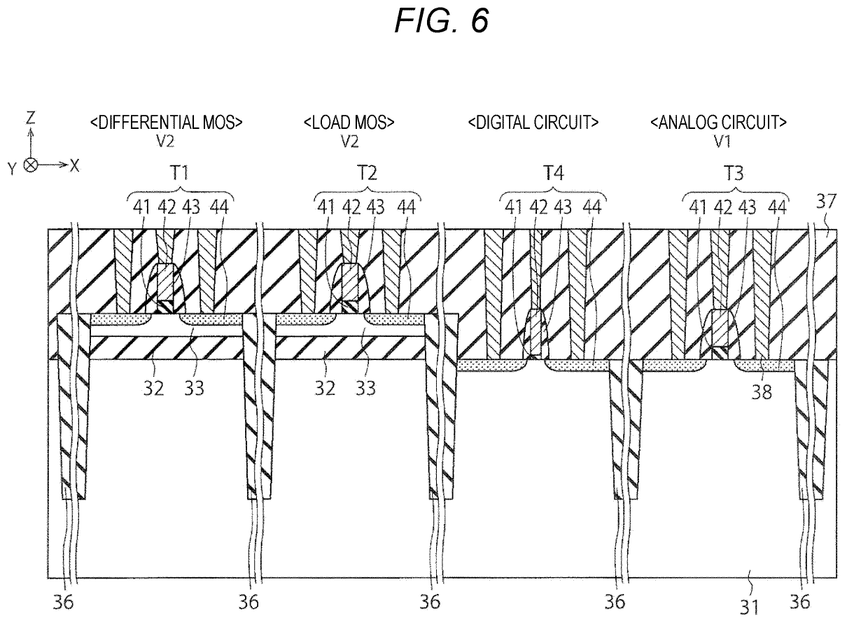

FIG. 6 is a cross-sectional view illustrating a structure of a solid-state imaging device according to a second embodiment.

The solid-state imaging device (FIG. 6) of the present embodiment has a structure similar to that of the solid-state imaging device (FIG. 5) of the first embodiment. However, the transistor T4 of the present embodiment is formed not on the semiconductor layer 33 but on the semiconductor substrate 31. Therefore, the source/drain region 44 of the transistor T4 of the present embodiment is formed in the semiconductor substrate 31. The transistors T3 and T4 of the present embodiment are each an example of a first transistor of the present disclosure, and the transistors T1 and T2 of the present embodiment are each an example of a second transistor of the present disclosure.

In the first embodiment, the transistor in the digital circuit is designed to be the LV transistor, and disposed on the SOI structure as in the transistor T4 illustrated in FIG. 5.

This makes it possible to reduce power consumption of the digital circuit. In contrast, in the present embodiment, the transistor in the digital circuit is designed to be the LV transistor, and disposed on the bulk semiconductor substrate as in the transistor T4 illustrated in FIG. 6. This makes it possible to suppress the labor and cost of recreating the transistor model in the digital circuit from the model for the bulk semiconductor substrate to the model for the SOI structure.

The transistor in the digital circuit may be disposed on the SOI structure as in the first embodiment, or may be disposed on the bulk semiconductor substrate as in the present embodiment. In a case where it is desirable to reduce the power consumption of the digital circuit, it is desirable to employ the digital circuit of the first embodiment. Contrarily, in a case where it is desirable not to recreate the model of the transistor in the digital circuit, it is desirable to employ the digital circuit of the present embodiment.

As described above, in the present embodiment, the ULVT transistors in the comparison circuit 13 and the load circuit 12 are formed on the SOI structure, and the SVT transistor in the other analog circuit and the LV transistor in the digital circuit are formed on the bulk semiconductor substrate. Therefore, according to the present embodiment, these transistors can be suitably formed on the SOI structure and the bulk semiconductor substrate. For example, disposing the ULVT transistor on the SOI structure makes it possible to reduce the leakage current of the ULVT transistor in which the leakage current is likely to be a problem. Furthermore, limiting the transistors disposed on the SOI structure to some transistors makes it possible to reduce labor and cost for recreating the model.

Note that the digital circuit of the present embodiment may include not only an LV transistor but also a ULVT transistor or an SVT transistor. In this case, the ULVT transistor may be disposed on the SOI structure.

### Application Example

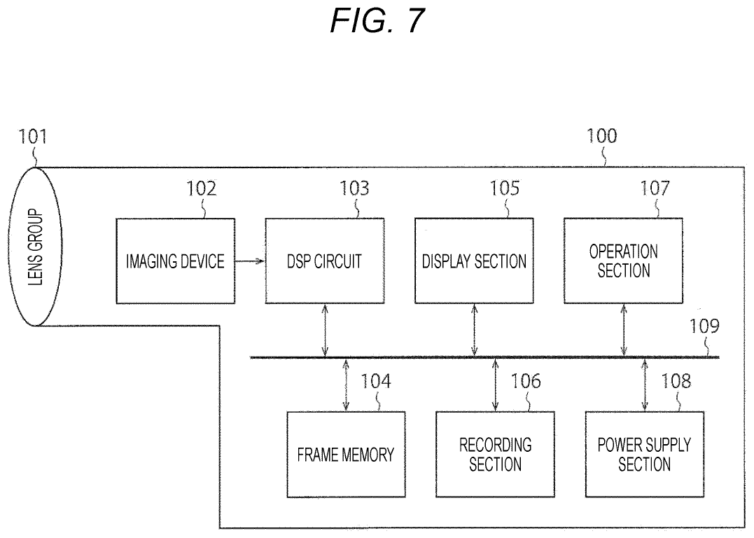

FIG. 7 is a block diagram illustrating a configuration example of the electronic device. The electronic device illustrated in FIG. 7 is a camera 100.

The camera 100 includes an optical section 101 including a lens group and the like, an imaging device 102 that is the solid-state imaging device according to the first or the second embodiment, a digital signal processor (DSP) circuit 103 that is a camera signal processing circuit, a frame memory 104, a display section 105, a recording section 106, an operation section 107, and a power supply section 108. Furthermore, the DSP circuit 103, the frame memory 104, the display section 105, the recording section 106, the operation section 107, and the power supply section 108 are connected to each other via a bus line 109.

The optical section 101 captures incident light (image light) from a subject and forms an image on an imaging surface of the imaging device 102. The imaging device 102 converts a light amount of incident light formed into an image on the imaging surface by the optical section 101 into an electric signal on a pixel-by-pixel basis and outputs the electric signal as a pixel signal.

The DSP circuit 103 performs signal processing on the pixel signal output from the imaging device 102. The frame memory 104 is a memory for storing one screen of a moving image or a still image captured by the imaging device 102.

The display section 105 includes, for example, a panel type display device such as a liquid crystal panel or an organic EL panel, and displays a moving image or a still image captured by the imaging device 102. The recording section 106 records a moving image or a still image captured by the imaging device 102 on a recording medium such as a hard disk or a semiconductor memory.

The operation section 107 issues operation commands for various functions of the camera 100 in response to an operation performed by a user. The power supply section 108 appropriately supplies various power supplies, which are operation power supplies for the DSP circuit 103, the frame memory 104, the display section 105, the recording section 106, and the operation section 107, to these power supply targets.

By using the solid-state imaging device according to the first or the second embodiment as the imaging device 102, acquisition of a good image can be expected.

The solid-state imaging device can be applied to various other products. For example, the solid-state imaging device may be mounted on any type of moving bodies such as vehicles, electric vehicles, hybrid electric vehicles, motorcycles, bicycles, personal mobility, airplanes, drones, ships, and robots.

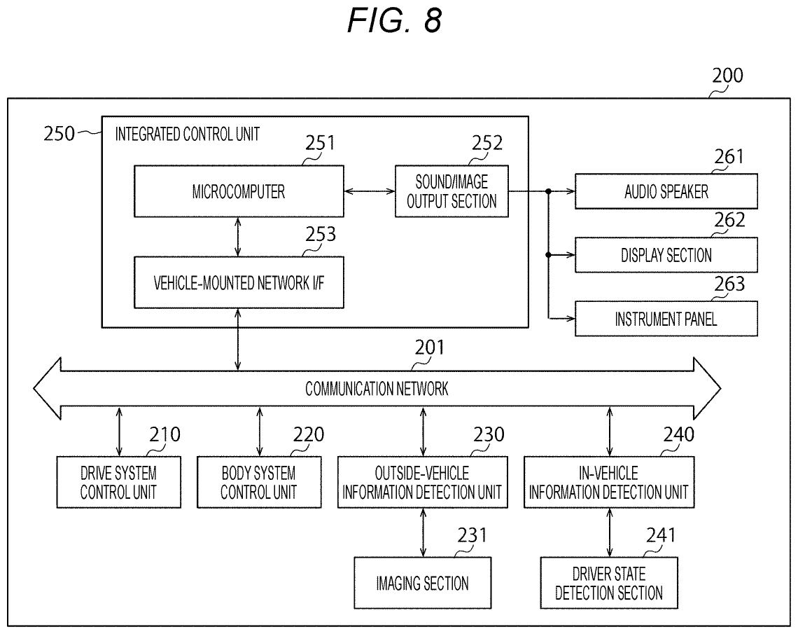

FIG. 8 is a block diagram illustrating a configuration example of a moving body control system. The moving body control system illustrated in FIG. 8 is a vehicle control system 200.

The vehicle control system 200 includes a plurality of electronic control units connected to each other via a communication network 201. In the example illustrated in FIG. 8, the vehicle control system 200 includes a drive system control unit 210, a body system control unit 220, an outside-vehicle information detection unit 230, an in-vehicle information detection unit 240, and an integrated control unit 250. FIG. 8 further illustrates a microcomputer 251, a sound/image output section 252, and a vehicle-mounted network interface (I/F) 253 as components of the integrated control unit 250.

The drive system control unit 210 controls the operation of devices related to a driving system of a vehicle in accordance with various types of programs. For example, the drive system control unit 210 functions as a control device for a driving force generating device for generating a driving force of a vehicle, such as an internal combustion engine, a driving motor, or the like, a driving force transmitting mechanism for transmitting the driving force to wheels, a steering mechanism for adjusting a steering angle of the vehicle, a braking device for generating a braking force of the vehicle, and the like.

The body system control unit 220 controls the operation of various types of devices provided on a vehicle body in accordance with various types of programs. For example, the body system control unit 220 functions as a control device for a smart key system, a keyless entry system, a power window device, or various types of lamps (for example, a headlamp, a backup lamp, a brake lamp, a turn signal, a fog lamp, or the like) . In this case, radio waves transmitted from a mobile device as an alternative to a key or signals of various types of switches can be input to the body system control unit 220. The body system control unit 220 receives inputs of such radio waves or signals, and controls a door lock device, the power window device, the lamps, or the like of the vehicle.

The outside-vehicle information detection unit 230 detects information of the outside of the vehicle equipped with the vehicle control system 200. The outside-vehicle information detection unit 230 is connected with, for example, an imaging section 231. The outside-vehicle information detection unit 230 makes the imaging section 231 capture an image of the outside of the vehicle, and receives the captured image from the imaging section 231. On the basis of the received image, the outside-vehicle information detection unit 230 may perform processing of detecting an object such as a human, an automobile, an obstacle, a sign, a character on a road surface, or the like, or processing of detecting a distance thereto.

The imaging section 231 is an optical sensor that receives light and that outputs an electric signal corresponding to the amount of received light. The imaging section 231 can output the electric signal as an image, or can output the electric signal as information on a measured distance. The light received by the imaging section 231 may be visible light, or may be invisible light such as infrared light or the like. The imaging section 231 includes the solid-state imaging device according to the first or the second embodiment.

The in-vehicle information detection unit 240 detects information of the inside of the vehicle equipped with the vehicle control system 200. The in-vehicle information detection unit 240 is, for example, connected with a driver state detection section 241 that detects a state of a driver. For example, the driver state detection section 241 includes a camera that captures an image of the driver, and on the basis of detection information input from the driver state detection section 241, the in-vehicle information detection unit 240 may calculate a degree of fatigue of the driver or a degree of concentration of the driver, or may determine whether or not the driver is dozing off. The camera may include the solid-state imaging device according to the first or the second embodiment, and may be, for example, the camera 100 illustrated in FIG. 7.

The microcomputer 251 can calculate a control target value for the driving force generating device, the steering mechanism, or the braking device on the basis of the information on the inside or outside of the vehicle obtained by the outside-vehicle information detection unit 230 or the in-vehicle information detection unit 240, and output a control command to the drive system control unit 210. For example, the microcomputer 251 can perform cooperative control intended to implement functions of an advanced driver assistance system (ADAS), the functions including collision avoidance or shock mitigation for the vehicle, following traveling based on a following distance, vehicle speed maintaining traveling, a warning of collision of the vehicle, a warning of deviation of the vehicle from a lane, and the like.

Furthermore, the microcomputer 251 can perform cooperative control intended for automated driving or the like in which the vehicle travels autonomously without depending on the operation of the driver by controlling the driving force generating device, the steering mechanism, or the braking device on the basis of the information of the surroundings of the vehicle obtained by the outside-vehicle information detection unit 230 or the in-vehicle information detection unit 240.

Furthermore, the microcomputer 251 can output a control command to the body system control unit 220 on the basis of the information of the outside of the vehicle obtained by the outside-vehicle information detection unit 230. For example, the microcomputer 251 can perform cooperative control for the purpose of preventing glare, such as switching from a high beam to a low beam, by controlling the headlamp according to the position of a preceding vehicle or an oncoming vehicle detected by the outside-vehicle information detection unit 230.

The sound/image output section 252 transmits an output signal of at least one of a sound or an image to an output device that can visually or auditorily provide information to an occupant of the vehicle or the outside of the vehicle. In the example of FIG. 8, an audio speaker 261, a display section 262, and an instrument panel 263 are illustrated as such output device. The display section 262 may, for example, include an on-board display or a head-up display.

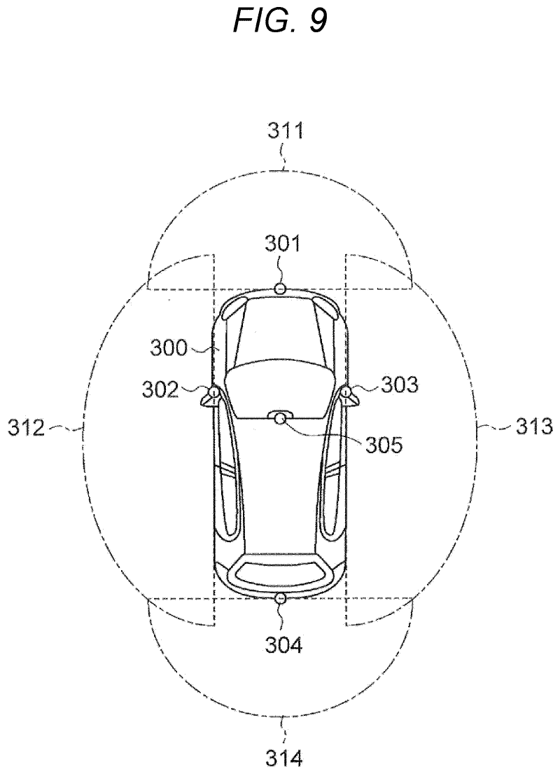

FIG. 9 is a plan view illustrating a specific example of a setting position of the imaging section 231 in FIG. 8.

A vehicle 300 illustrated in FIG. 9 includes imaging sections 301, 302, 303, 304, and 305 as the imaging sections 231. The imaging sections 301, 302, 303, 304, and 305 are, for example, provided at positions on a front nose, side mirrors, a rear bumper, and a back door of the vehicle 300, and on an upper portion of a windshield in the interior of the vehicle.

The imaging section 301 provided on the front nose mainly acquires an image of the front of the vehicle 300. The imaging section 302 provided on the left side mirror and the imaging section 303 provided on the right side mirror mainly acquire images of the sides of the vehicle 300. The imaging section 304 provided on the rear bumper or the back door mainly acquires an image of the rear of the vehicle 300. The imaging section 305 provided on the upper portion of the windshield in the interior of the vehicle mainly acquires an image of the front of the vehicle 300. The imaging section 305 is used to detect, for example, a preceding vehicle, a pedestrian, an obstacle, a traffic light, a traffic sign, a lane, and the like.

FIG. 9 illustrates an example of imaging ranges of the imaging sections 301, 302, 303, and 304 (hereinafter referred to as “imaging sections 301 to 304”). An imaging range 311 represents the imaging range of the imaging section 301 provided on the front nose. An imaging range 312 represents the imaging range of the imaging section 302 provided on the left side mirror. An imaging range 313 represents the imaging range of the imaging section 303 provided on the right side mirror. An imaging range 314 represents the imaging range of the imaging section 304 provided on the rear bumper or the back door. For example, an overhead view of the vehicle 300 as viewed from above is obtained by superimposing image data captured by the imaging sections 301 to 304. Hereinafter, the imaging ranges 311, 312, 313, and 314 are referred to as the “imaging ranges 311 to 314”.

At least one of the imaging sections 301 to 304 may have a function of acquiring distance information. For example, at least one of the imaging sections 301 to 304 may be a stereo camera including a plurality of imaging devices or an imaging device including pixels for phase difference detection.

For example, the microcomputer 251 (FIG. 8) can determine a distance to each three-dimensional object within the imaging ranges 311 to 314 and a temporal change in the distance (relative speed with respect to the vehicle 300) on the basis of the distance information obtained from the imaging sections 301 to 304. On the basis of the calculation results, the microcomputer 251 can extract, as a preceding vehicle, a nearest three-dimensional object that is present on a traveling path of the vehicle 300 and travels in substantially the same direction as the vehicle 300 at a predetermined speed (for example, equal to or more than 0 km/h) . Moreover, the microcomputer 251 can set a following distance to be maintained in front of a preceding vehicle in advance, and perform automatic brake control (including following stop control), automatic acceleration control (including following start control), or the like. According to this example, the cooperative control intended for automated driving that makes the vehicle travel autonomously and the like can be performed without depending on the operation of the driver.

For example, the microcomputer 251 can classify three-dimensional object data related to three-dimensional objects into a two-wheeled vehicle, a standard-sized vehicle, a large-sized vehicle, a pedestrian, a utility pole, and other three-dimensional objects on the basis of the distance information obtained from the imaging sections 301 to 304, extract the classified three-dimensional object data, and use the extracted three-dimensional object data for automatic avoidance of an obstacle. For example, the microcomputer 251 identifies obstacles around the vehicle 300 as obstacles that the driver of the vehicle 300 can recognize visually and obstacles that are difficult for the driver of the vehicle 300 to recognize visually. Then, the microcomputer 251 determines a collision risk indicating a risk of collision with each obstacle, and in a situation in which the collision risk is equal to or higher than a set value and there is thus a possibility of collision, the microcomputer 251 outputs a warning to the driver via the audio speaker 261 or the display section 262, and performs forced deceleration or avoidance steering via the drive system control unit 210 to assist in driving to avoid collision.

At least one of the imaging sections 301 to 304 may be an infrared camera that detects infrared light. The microcomputer 251 can, for example, recognize a pedestrian by determining whether or not there is a pedestrian in images captured by the imaging sections 301 to 304. Such recognition of a pedestrian is, for example, performed by a procedure of extracting characteristic points in the images captured by the imaging sections 301 to 304 as infrared cameras and a procedure of determining whether or not an object is a pedestrian by performing pattern matching processing on a series of characteristic points representing the contour of the object. In a case where the microcomputer 251 determines that there is a pedestrian in the captured images captured by the imaging sections 301 to 304 and recognizes the pedestrian, the sound/image output section 252 controls the display section 262 so that a square contour line for emphasis is displayed in a superimposed manner on the recognized pedestrian. Furthermore, the sound/image output section 252 may also control the display section 262 so that an icon or the like representing the pedestrian is displayed at a desired position.

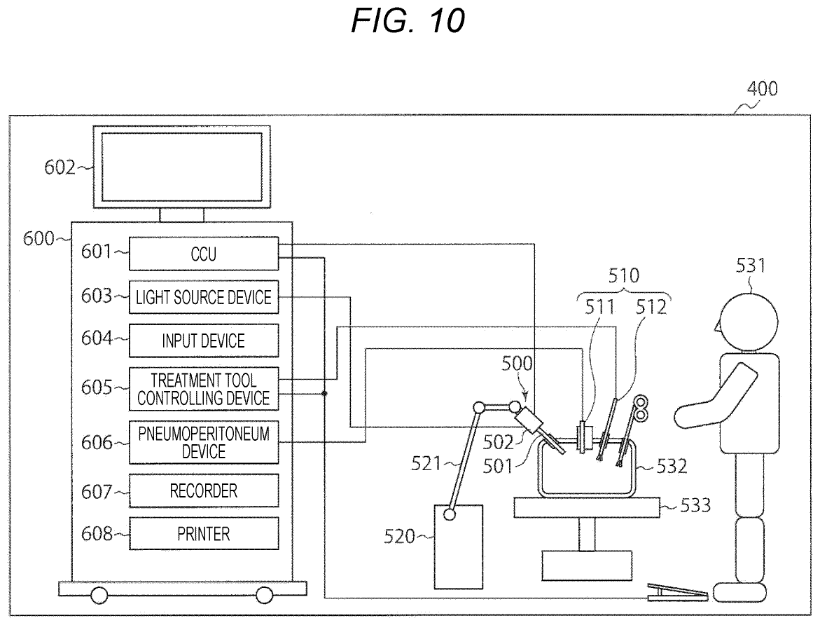

FIG. 10 is a view illustrating an example of a schematic configuration of an endoscopic surgical system to which the technology according to an embodiment of the present disclosure (present technology) can be applied.

In FIG. 10, a state is illustrated in which a surgeon (medical doctor) 531 is using an endoscopic surgical system 400 to perform surgery for a patient 532 on a patient bed 533. As illustrated, the endoscopic surgical system 400 includes an endoscope 500, other surgical tools 510 such as a pneumoperitoneum tube 511 and an energy treatment tool 512, a supporting arm device 520 for supporting the endoscope 500, and a cart 600 on which various devices for endoscopic surgery are mounted.

The endoscope 500 includes a lens barrel 501 including a region of a predetermined length from a distal end thereof to be inserted into a body cavity of the patient 532, and a camera head 502 connected to a proximal end of the lens barrel 501.

Although the illustrated example illustrates the endoscope 500 is configured as a so-called rigid endoscope having a rigid lens barrel 501, the endoscope 500 may be a so-called flexible endoscope having a flexible lens barrel.

An opening in which an objective lens is fitted is provided at the distal end of the lens barrel 501. A light source device 603 is connected to the endoscope 500, and light generated by the light source device 603 is guided to the distal end of the lens barrel by a light guide extending in the lens barrel 501 and is emitted to an observation target in the body cavity of the patient 532 through the objective lens. Note that the endoscope 500 may be a forward-viewing endoscope, an oblique-viewing endoscope, or a side-viewing endoscope.

An optical system and an imaging element are provided in the camera head 502, and light reflected by the observation target (observation light) is collected on the imaging element by the optical system. The observation light is photoelectrically converted by the imaging element to generate an electric signal corresponding to the observation light, namely, an image signal corresponding to an observation image. The image signal is transmitted to a camera control unit (CCU) 601 as RAW data.

The CCU 601 includes a central processing unit (CPU), a graphics processing unit (GPU), and the like, and integrally controls the operations of the endoscope 500 and a display device 602. Moreover, the CCU 601 receives the image signal from the camera head 502 and applies, on the image signal, various types of image processing, for example, development processing (demosaicing processing) or the like for displaying an image based on the image signal.

The display device 602 displays the image based on the image signal which has been subjected to the image processing by the CCU 601 under the control of the CCU 601.

The light source device 603 includes, for example, a light source such as a light emitting diode (LED), and supplies irradiation light for capturing an image of a surgical site or the like to the endoscope 500.

An input device 604 is an input interface for the endoscopic surgical system 11000. A user may input various types of information and instructions to the endoscopic surgical system 400 via the input device 604. For example, the user inputs an instruction and the like to change an imaging condition (type of irradiation light, magnification, focal length and the like) by the endoscope 500.

A treatment tool control device 605 controls driving of the energy treatment tool 512 for tissue cauterization, incision, blood vessel sealing, and the like. A pneumoperitoneum device 606 sends gas into the body cavity of the patient 532 via the pneumoperitoneum tube 511 in order to inflate the body cavity for a purpose of securing a field of view by the endoscope 500 and securing work space for the surgeon. A recorder 607 is a device that can record various types of information regarding surgery. A printer 608 is a device that can print various types of information regarding surgery in various formats such as a text, an image, or a graph.

Note that the light source device 603 which supplies the irradiation light for imaging the surgical site to the endoscope 500 may include, for example, an LED, a laser light source, or a white light source obtained by combining these. In a case where the white light source includes a combination of RGB laser light sources, because an output intensity and an output timing of each color (each wavelength) can be controlled with high accuracy, the light source device 603 can adjust white balance of a captured image. Furthermore, in this case, by irradiating the observation target with the laser light from each of the R, G, and B laser light sources in time division and controlling driving of the imaging element of the camera head 502 in synchronism with the irradiation timing, images corresponding to R, G, and B can be captured in time division. According to this method, a color image can be obtained even if color filters are not provided for the imaging element.

Furthermore, the driving of the light source device 603 may be controlled so that the intensity of light to be output is changed every predetermined time. By controlling driving of the imaging element of the camera head 502 in synchronism with the timing of the change of the intensity of light to acquire images time-divisionally and synthesizing the images, an image of a high dynamic range free from underexposed blocked up shadows and overexposed highlights can be created.

Furthermore, the light source device 603 may be able to supply light in a predetermined wavelength band adapted to special light observation. In special light observation, for example, by utilizing the wavelength dependency of absorption of light in a body tissue to radiate light of a narrow band in comparison with irradiation light upon ordinary observation (namely, white light), narrow band imaging of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating the body tissue with excitation light (autofluorescence observation) or to obtain a fluorescent light image by locally injecting a reagent such as indocyanine green (ICG) into a body tissue and irradiating the body tissue with excitation light corresponding to a fluorescent light wavelength of the reagent. The light source device 603 can be configured to supply narrow band light and/or excitation light adapted to such special light observation.

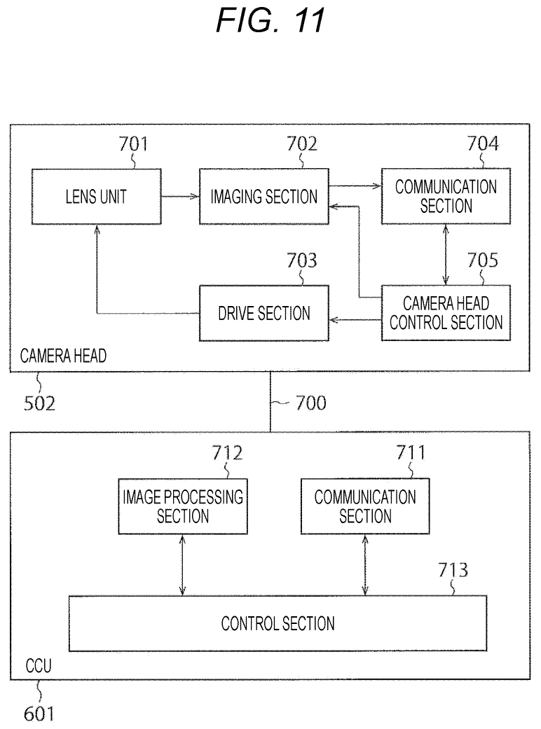

FIG. 11 is a block diagram illustrating an example of a functional configuration of the camera head 502 and the CCU 601 illustrated in FIG. 10.

The camera head 502 includes a lens unit 701, an imaging section 702, a drive section 703, a communication section 704, and a camera head control section 705. The CCU 601 includes a communication section 711, an image processing section 712, and a control section 713. The camera head 502 and the CCU 601 are connected to each other communicably by a transmission cable 700.

The lens unit 701 is an optical system provided at a connection portion with the lens barrel 501. The observation light captured from the distal end of the lens barrel 501 is guided to the camera head 502 and enters the lens unit 701. The lens unit 701 is configured by combining a plurality of lenses including a zoom lens and a focus lens.

The imaging section 702 includes an imaging element. The number of imaging elements included in the imaging section 702 may be one (so-called single plate type) or two or more (so-called multiple plate type). In a case where the imaging section 702 is configured as the multiple plate type, for example, image signals corresponding to R, G, and B may be generated by the respective imaging elements, and a color image may be obtained by synthesizing the generated image signals. Alternatively, the imaging section 702 may include a pair of imaging elements for obtaining right-eye and left-eye image signals corresponding to three-dimensional (3D) display. By performing the 3D display, the surgeon 531 can grasp a depth of a living body tissue in a surgical site more accurately. Note that, in a case where the imaging section 702 is configured as the multiple plate type, a plurality of systems of the lens units 701 may be provided so as to correspond to the respective imaging elements. The imaging section 702 is, for example, the solid-state imaging device according to the first or the second embodiments.

Furthermore, the imaging section 702 is not necessarily provided in the camera head 502. For example, the imaging section 702 may be provided inside the lens barrel 501 immediately behind the objective lens.

The drive section 703 includes an actuator and moves the zoom lens and the focusing lens of the lens unit 701 by a predetermined distance along an optical axis under the control of the camera head control section 705. With this arrangement, the magnification and focus of the image captured by the imaging section 702 may be appropriately adjusted.

The communication section 704 includes a communication device for transmitting and receiving various types of information to and from the CCU 601. The communication section 704 transmits the image signal obtained from the imaging section 702 as the RAW data to the CCU 601 via the transmission cable 700.

Furthermore, the communication section 704 receives a control signal for controlling driving of the camera head 502 from the CCU 601 and supplies the control signal to the camera head control section 705. The control signal includes information regarding imaging conditions such as, for example, information that a frame rate of an image to be captured is designated, information that an exposure value upon image capturing is designated and/or information that a magnification and a focus of an image to be captured are designated.

Note that the imaging conditions such as the frame rate, exposure value, magnification, and focus described above may be appropriately specified by the user, or may be automatically set by the control section 713 of the CCU 601 on the basis of the acquired image signal. In the latter case, the endoscope 500 is equipped with a so-called auto exposure (AE) function, an auto focus (AF) function, and an auto white balance (AWB) function.

The camera head control section 705 controls the driving of the camera head 502 on the basis of the control signal from the CCU 601 received via the communication section 704.

The communication section 711 includes a communication device for transmitting and receiving various types of information to and from the camera head 502. The communication section 711 receives the image signal transmitted from the camera head 502 via the transmission cable 700.

Furthermore, the communication section 711 transmits the control signal for controlling the driving of the camera head 502 to the camera head 502. The image signal and the control signal can be transmitted by electrical communication, optical communication or the like.

The image processing section 712 performs various types of image processing on the image signal which is the RAW data transmitted from the camera head 502.

The control section 713 performs various types of control regarding imaging of the surgical site and the like by the endoscope 500 and display of the captured image obtained by the imaging of the surgical site and the like. For example, the control section 713 generates the control signal for controlling the driving of the camera head 502.

Furthermore, the control section 713 causes the display device 602 to display the captured image including the surgical site and the like on the basis of the image signal subjected to the image processing by the image processing section 712. At this time, the control section 713 may recognize various objects in the captured image using various image recognition technologies. For example, the control section 713 may detect edge shapes, colors, and the like of the objects included in the captured image, to recognize the surgical tool such as forceps, a specific living body site, bleeding, mist when the energy treatment tool 512 is used, and the like. At the time of causing the display device 602 to display the captured image, the control section 713 may display various types of surgery assistance information on the image of the surgical site in a superimposed manner using the recognition result. The surgery assistance information is displayed in a superimposed manner and presented to the surgeon 531, which can reduce the burden on the surgeon 531 and enable the surgeon 531 to reliably proceed with surgery.

The transmission cable 700 connecting the camera head 502 and the CCU 601 is an electric signal cable compatible with communication of electric signals, an optical fiber compatible with optical communication, or a composite cable thereof.

Here, in the illustrated example, the communication is performed wired using the transmission cable 700, but the communication between the camera head 502 and the CCU 601 may be performed wirelessly.

Although the embodiments of the present disclosure have been described above, these embodiments may be implemented with various modifications within a scope not departing from the gist of the present disclosure. For example, a plurality of embodiments may be implemented in combination.

Note that the present disclosure can also have the following configurations.

### 1

A solid-state imaging device including:
a semiconductor substrate;
an insulating film provided on the semiconductor substrate;
a semiconductor layer provided on the insulating film; and
a plurality of transistors including one or more first transistors and one or more second transistors, the one or more first transistors each including a source/drain region in the semiconductor substrate, the one or more second transistors each including a source/drain region in the semiconductor layer, in which
the plurality of transistors includes:
a low-voltage transistor including a gate insulating film having a first film thickness;
a first high-voltage transistor that includes a gate insulating film having a second film thickness larger than the first film thickness and has a first threshold voltage; and
a second high-voltage transistor that includes a gate insulating film having the second film thickness and has a second threshold voltage lower than the first threshold voltage, and
the second high-voltage transistor is included in the second transistors.

### 2

The solid-state imaging device according to (1), in which the low-voltage transistor is included in the second transistors.

### 3

The solid-state imaging device according to (1), in which the low-voltage transistor is included in the first transistors.

### 4

The solid-state imaging device according to (1), in which the low-voltage transistor is provided in a digital circuit.

### 5

The solid-state imaging device according to (1), in which the first high-voltage transistor is included in the first transistors.

### 6

The solid-state imaging device according to (1), in which the first high-voltage transistor is provided in an analog circuit.

### 7

The solid-state imaging device according to (6), in which the first high-voltage transistor is provided in the analog circuit other than a comparison circuit and a load circuit.

### 8

The solid-state imaging device according to (1), in which the second high-voltage transistor is provided in a comparison circuit or a load circuit.

### 9

The solid-state imaging device according to (8), in which the second high-voltage transistor in the comparison circuit is provided in a differential circuit.

### 10

The solid-state imaging device according to (8), in which
the second high-voltage transistor in the comparison circuit has a first conductivity type, and
the second high-voltage transistor in the load circuit has a second conductivity type different from the first conductivity type.

### 11

The solid-state imaging device according to (1), in which the semiconductor layer is formed with the same semiconductor material as the semiconductor substrate.

### 12

The solid-state imaging device according to (11), in which the semiconductor material is silicon.

### 13

The solid-state imaging device according to (1), in which the insulating film is an oxide film.

### 14

A solid-state imaging device including:
a semiconductor substrate;
an insulating film provided on the semiconductor substrate;
a semiconductor layer provided on the insulating film; and
a plurality of transistors including one or more first transistors and one or more second transistors, the one or more first transistors each including a source/drain region in the semiconductor substrate, the one or more second transistors each including a source/drain region in the semiconductor layer, in which the second transistors include a transistor provided in a comparison circuit or a load circuit.

### 15

The solid-state imaging device according to (14), in which the transistor in the comparison circuit is provided in a differential circuit.

### 16

The solid-state imaging device according to (14), in which
the transistor in the comparison circuit has a first conductivity type, and
the transistor in the load circuit has a second conductivity type different from the first conductivity type.

### 17

The solid-state imaging device according to (14), in which the first transistors include a transistor provided in an analog circuit other than the comparison circuit and the load circuit.

### 18

The solid-state imaging device according to (14), in which the first transistors or the second transistors include a transistor provided in a digital circuit.

### 19

The solid-state imaging device according to (14), in which
the plurality of transistors includes:
a low-voltage transistor including a gate insulating film having a first film thickness;
a first high-voltage transistor that includes a gate insulating film having a second film thickness larger than the first film thickness and has a first threshold voltage; and
a second high-voltage transistor that includes a gate insulating film having the second film thickness and has a second threshold voltage lower than the first threshold voltage, and
the second high-voltage transistor is included in the second transistors and is provided in the comparison circuit or the load circuit.

### 20

The solid-state imaging device according to (19), in which
the first high-voltage transistor is included in the first transistors and is provided in an analog circuit other than the comparison circuit and the load circuit, and
the low-voltage transistor is included in the first transistors or the second transistors and is provided in a digital circuit.

### REFERENCE SIGNS LIST

1 pixel
2 vertical signal line
3 horizontal signal line
11 pixel array region
12 load circuit
13 comparison circuit
14 counter circuit
15 horizontal scanning circuit
16 vertical scanning circuit
17 DA converter
18 charge pump
21 scanning control unit
22 PS converter
23 delay line
24 transmission unit
25 sense amplifier
26 PLL
31 semiconductor substrate
31a bulk region
31b N well region
31c P well region
31d back plate region
31e back plate region
32 embedded insulating film
33 semiconductor layer
35 contact layer
36 element isolation insulating film
37 Interlayer insulating film
38 contact plug
41 gate insulating film
42 gate electrode
43 sidewall insulating film
44 source/drain region

1. A solid-state imaging device comprising:
a semiconductor substrate;
an insulating film provided on the semiconductor substrate;
a semiconductor layer provided on the insulating film; and
a plurality of transistors including one or more first transistors and one or more second transistors, the one or more first transistors each including a source/drain region in the semiconductor substrate, the one or more second transistors each including a source/drain region in the semiconductor layer, wherein
the plurality of transistors includes:
a low-voltage transistor including a gate insulating film having a first film thickness;
a first high-voltage transistor that includes a gate insulating film having a second film thickness larger than the first film thickness and has a first threshold voltage; and
a second high-voltage transistor that includes a gate insulating film having the second film thickness and has a second threshold voltage lower than the first threshold voltage, and
the second high-voltage transistor is included in the second transistors.

2. The solid-state imaging device according to claim 1, wherein the low-voltage transistor is included in the second transistors.

3. The solid-state imaging device according to claim 1, wherein the low-voltage transistor is included in the first transistor.

4. The solid-state imaging device according to claim 1, wherein the low-voltage transistor is provided in a digital circuit.

5. The solid-state imaging device according to claim 1, wherein the first high-voltage transistor is included in the first transistors.

6. The solid-state imaging device according to claim 1, wherein the first high-voltage transistor is provided in an analog circuit.

7. The solid-state imaging device according to claim 6, wherein the first high-voltage transistor is provided in the analog circuit other than a comparison circuit and a load circuit.

8. The solid-state imaging device according to claim 1, wherein the second high-voltage transistor is provided in a comparison circuit or a load circuit.

9. The solid-state imaging device according to claim 8, wherein the second high-voltage transistor in the comparison circuit is provided in a differential circuit.

10. The solid-state imaging device according to claim 8, wherein
the second high-voltage transistor in the comparison circuit has a first conductivity type, and
the second high-voltage transistor in the load circuit has a second conductivity type different from the first conductivity type.

11. The solid-state imaging device according to claim 1, wherein the semiconductor layer is formed with the same semiconductor material as the semiconductor substrate.

12. The solid-state imaging device according to claim 11, wherein the semiconductor material is silicon.

13. The solid-state imaging device according to claim 1, wherein the insulating film is an oxide film.

14. A solid-state imaging device comprising:
a semiconductor substrate;
an insulating film provided on the semiconductor substrate;
a semiconductor layer provided on the insulating film; and
a plurality of transistors including one or more first transistors and one or more second transistors, the one or more first transistors each including a source/drain region in the semiconductor substrate, the one or more second transistors each including a source/drain region in the semiconductor layer,
wherein the second transistors include a transistor provided in a comparison circuit or a load circuit.

15. The solid-state imaging device according to claim 14, wherein the transistor in the comparison circuit is provided in a differential circuit.

16. The solid-state imaging device according to claim 14, wherein
the transistor in the comparison circuit has a first conductivity type, and
the transistor in the load circuit has a second conductivity type different from the first conductivity type.

17. The solid-state imaging device according to claim 14, wherein the first transistors include a transistor provided in an analog circuit other than the comparison circuit and the load circuit.

18. The solid-state imaging device according to claim 14, wherein the first transistors or the second transistors include a transistor provided in a digital circuit.

19. The solid-state imaging device according to claim 14, wherein
the plurality of transistors includes:
a low-voltage transistor including a gate insulating film having a first film thickness;
a first high-voltage transistor that includes a gate insulating film having a second film thickness larger than the first film thickness and has a first threshold voltage; and
a second high-voltage transistor that includes a gate insulating film having the second film thickness and has a second threshold voltage lower than the first threshold voltage, and
the second high-voltage transistor is included in the second transistors and is provided in the comparison circuit or the load circuit.

20. The solid-state imaging device according to claim 19, wherein
the first high-voltage transistor is included in the first transistors and is provided in an analog circuit other than the comparison circuit and the load circuit, and
the low-voltage transistor is included in the first transistors or the second transistors and is provided in a digital circuit.
